(19) United States
(12) Patent Application Publication
(10) Pub. No.: US 2011/0117232 A1
(43) Pub. Date: May 19, 2011

(54) SEMICONDUCTOR CHIP PACKAGE WITH MOLD LOCKS

(76) Inventor: Jen-Chung Chen, Taipei County (TW)

(21) Appl. No.: 12/620,601

(22) Filed: Nov. 18, 2009

(51) Int. Cl. B29C 33/30; H01L 23/28

(52) U.S. Cl. 425/110; 257/787; 257/E23.116

(57) ABSTRACT

A semiconductor chip package is provided. A semiconductor chip package includes a base comprising a top surface and a bottom surface, the top surface comprising a die attach region and a through-hole forming region surrounding the die attach region, a die attached on the die attach region, a molding material encapsulating the die and a plurality of through holes filled up with the molding material formed in the through-hole forming region.

### BACKGROUND OF THE INVENTION

1. Field of the Invention

This invention relates generally to semiconductor packaging, and more specifically, to a semiconductor chip package with mold locks to anchor the molding material and prevent delamination of the molding material.

2. Description of the Prior Art

In a conventional method for a chip package, at least a die are electrically connected and mechanically bonded to a base. Typically, the die is encapsulated in a plastic molding compound in order to protect it from exposure to moisture or any contaminant during processing.

However, mechanical stress can build up between layers of the plastic molding compound and the base. Such stress typically stems from mismatch between the coefficient of thermal expansion (CTE) of the plastic molding compound and that of the base. The CTE of the mold compound is typically a poor match to the integrated circuit.

During operation, the chip goes through cycles of heating and cooling and may encounter brief thermal shocks. These heating and cooling cycles stress the chip package during expansion and contraction of different materials of the package. The stresses placed on the package during brief thermal shocks are significant, leading to weakened packages and immediate, catastrophic failure or defect such as so-called delamination. When the plastic molding compound delaminates from the base, the moisture may penetrate into the package molding compound, resulting in chip failure. Furthermore, delamination can damage the metal bonding wires that couple the base to the die.

It therefore becomes highly desirable to develop a package structure to prevent delamination, while preserve the integrity of the chip package.

### SUMMARY OF THE INVENTION

According to a preferred embodiment of the present invention, a semiconductor chip package includes a base comprising a top surface and a bottom surface, the top surface comprising a die attach region and a through-hole forming region surrounding the die attach region, a die attached on the die attach region, a molding material encapsulating the die and a plurality of through holes filled up with the molding material formed in the through-hole forming region.

According to another preferred embodiment of the present invention, a mold lock for a semiconductor chip package includes: a molding material with a tapered profile inlaid into an outer edge of a base.

According to another preferred embodiment of the present invention, a mold lock for a semiconductor chip package, includes: a molding material inlaid into an outer edge of a base, wherein the molding material has a mold bump protruding from a bottom surface of the base.

The mold locks of the preferred embodiment of the present invention work like anchors to interlock the entire molding material on the base and prevent delamination between the base and the molding material.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts a top view of a semiconductor chip package with mold locks.

FIG. 2 is a schematic, sectional view of a semiconductor chip package with mold locks taken along line A-A′ of FIG. 1.

FIG. 3 is a schematic, sectional view of a semiconductor chip package with mold locks taken alone line B-B′ of FIG. 1

FIG. 4 schematically depicts a variant of the mold lock structure.

FIG. 5 depicts a variant of the arrangement of the mold locks.

FIG. 6 depicts a schematic, sectional view of a semiconductor chip package with mold locks according to the second embodiment of the present invention taken along line A-A′ of FIG. 1.

FIG. 7 is another schematic, sectional view of a semiconductor chip package with mold locks taken alone line A-A′ of FIG. 1 according to the second embodiment of the present invention

FIG. 8 depicts a mold for fabricating the mold body and the mold locks in FIG. 2.

FIG. 9 depicts a mold for fabricating the mold body and the mold locks in FIG. 6.

### DETAILED DESCRIPTION

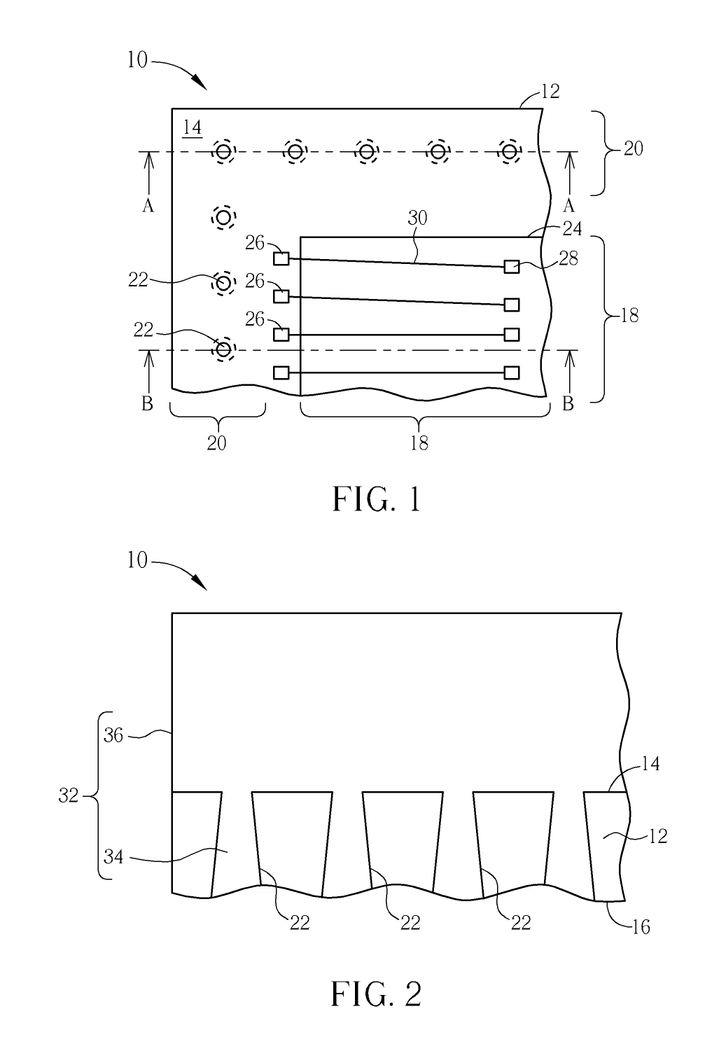

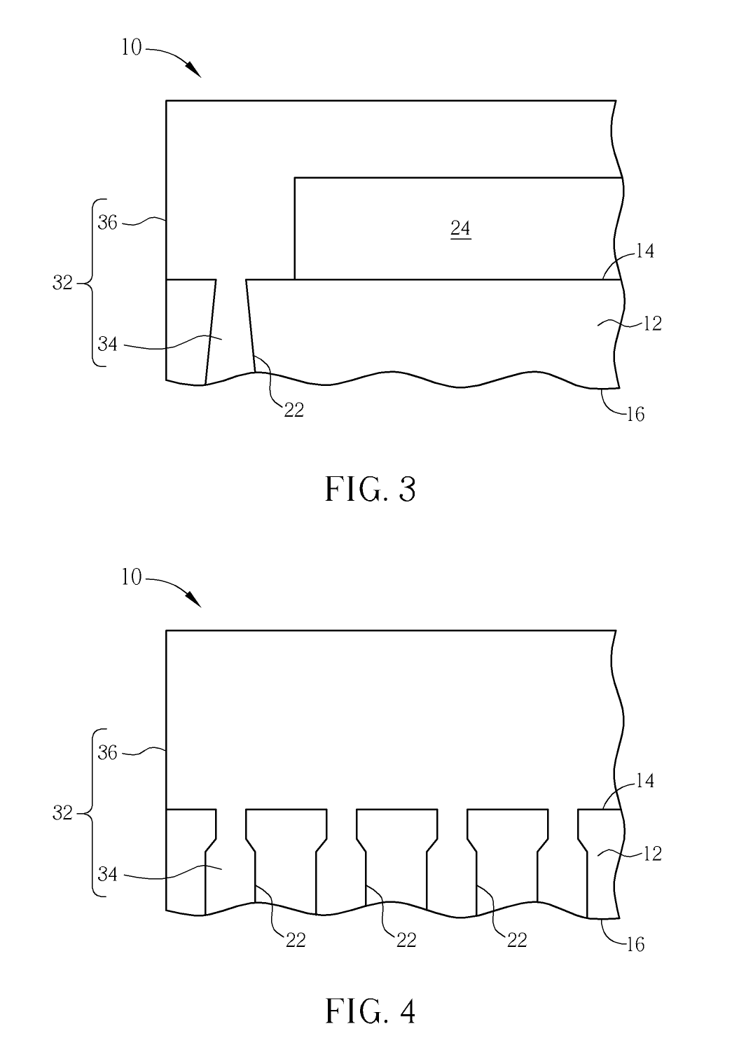

FIG. 1 schematically depicts a top view of a semiconductor chip package with mold locks. FIG. 2 is a schematic, sectional view of a semiconductor chip package with mold locks taken alone line A-A′ of FIG. 1 according to the first embodiment of the present invention. FIG. 3 is a schematic, sectional view of a semiconductor chip package with mold locks taken alone line B-B′ of FIG. 1. FIG. 4 depicts a variant of mold locks.

As shown in FIG. 1, FIG. 2 and FIG. 3, a semiconductor chip package 10 includes a base 12 having a top surface 14 and a bottom surface 16. For example, the base 12 may be a packaging substrate. The top surface 14 includes a die attach region 18 and a through-hole forming region 20. The through-hole forming region 20 is defined as the outer periphery area of the base 12 and it surrounds the die attach region 18. A plurality of through holes 22 are formed in the through-hole forming region 20, and a die 24 is mounted on the top surface 14 of the base 12 within the die attach region 18. According to the first embodiment of the present invention, the through holes 22 may be aligned with each other along a respective side edge of the base 12.

The semiconductor chip package 10 further includes a plurality of base conducting pads 26 disposed on the top surface 14. According to the first embodiment of the present invention, the base conducting pads 26 are arranged between the die attach region 18 and the through-hole forming region 20. A plurality of die conducting pads 28 are provided on the die 24. A bond wire 30 extending between one of the die conducting pads 28 and one of the base conducting pads 26 is provided to electrically connect the die 24 to the base 12.

It is noteworthy that the semiconductor chip package 10 has a molding material 32 encapsulating the die 24 and filling up the through holes 22. The molding material 32 filling into the through holes 22 anchors the molding material 32 to the base 12. The molding material 32 filling up the through holes 22 is hereinafter referred to as mold locks 34 inlaid into the through-hole forming region 20 of the base 12. The molding material 32 encapsulating the die 24 is hereinafter referred to as a mold body 36. The mold locks 34 interlock the mold body 36 to the base 12.

Each of the through holes 22 has a tapered profile broadening from the top surface 14, and each of the mold locks 34 is therefore shaped by the tapered profile of the corresponding through hole 22. As can be best seen in FIG. 2, the tapered profile of each through hole 22 is analogous to a frustum cone.

As shown in FIG. 4, the tapered profile of each through hole 22 can be a bottle-like shape. Of course, other shapes with a bottom surface larger than a top surface can be used as the profile of the through holes 22.

Since the tapered profile of through holes 22 has a widened bottom, the mold body 36 is tightly anchored onto the base 12 through the mold locks 34. Furthermore, the mold body 36 and the mold locks 34 constitute an integral and monolithic structure. The mold locks 34 have adequate strength to interlock the mold body 36 to the base 12. Accordingly, the delamination of the mold body 36 from the base 12 can be prevented.

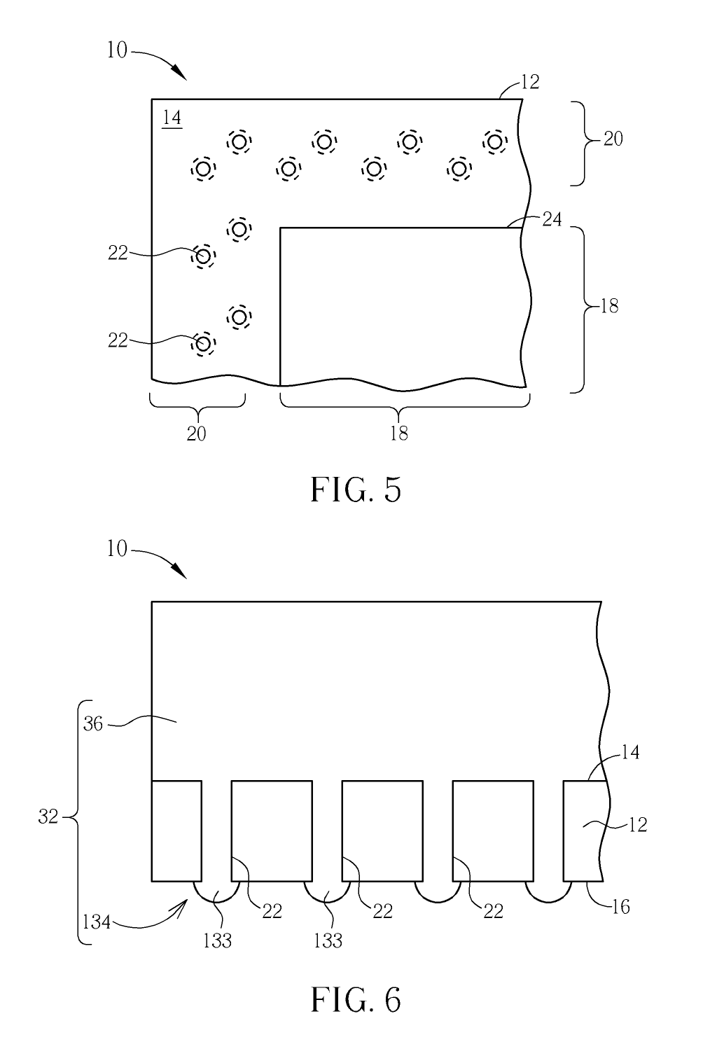

FIG. 5 depicts a variant of the arrangement of the mold locks. Although the through holes 22 are arranged aligned with each other along each side edge of the base 12 in FIG. 1, as shown in FIG. 5, the through holes 22 can be arranged in a staggered fashion.

FIG. 6 is a schematic, sectional view of a semiconductor chip package with mold locks taken alone line A-A′ of FIG. 1 according to the second embodiment of the present invention, wherein like elements, layers or regions are designated with like numeral numbers.

One difference between the semiconductor chip package in the first embodiment of FIG. 2 and the semiconductor chip package in the second embodiment of FIG. 6 is the shape of the mold locks. Other elements of FIG. 6 are generally in the same position and has the same function as those depicted in FIG. 2. Please refer to the previous description of FIG. 1 to FIG. 4 for reference.

As shown in FIG. 6, a semiconductor chip package 10 has a molding material 32 encapsulating a die 24, filling up the through holes 22 and forming a plurality of mold bumps 133 protruding from the bottom surface 16 of the base 12. Each of the mold bumps 133 integrates with the molding material 32 in each of the through holes 22. The molding material 32 filling up the through holes 22 and the mold bumps 133 together function as mold locks 134.

The mold locks 134 are inlaid into the through-hole forming region 20. The mold locks 134 anchor the mold body 36 to the base 12.

Preferably, each of the through holes 22 has a cylinder-shaped sectional profile, however, this invention should not be limited to such cylinder-shaped sectional profile. Other shapes or sectional profiles of the through holes 22 can be applied. Advantageously, each of the mold bumps 133 is spherical shaped. The protruding mold bumps 133 can increase the interlocking between the mold body 36 and the base 12.

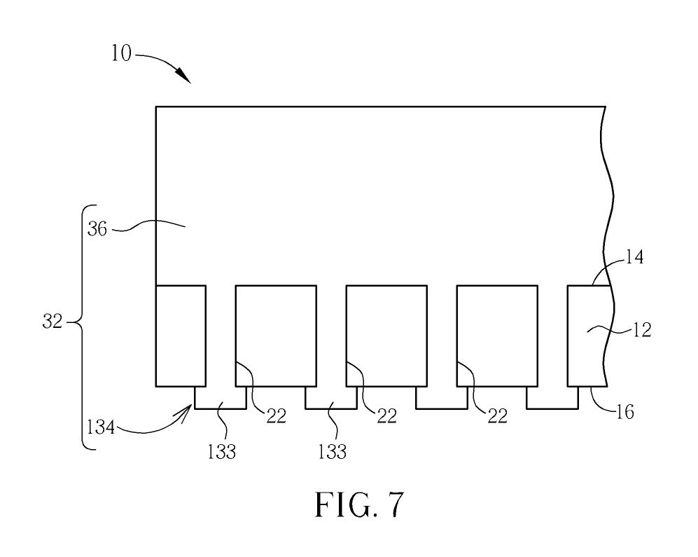

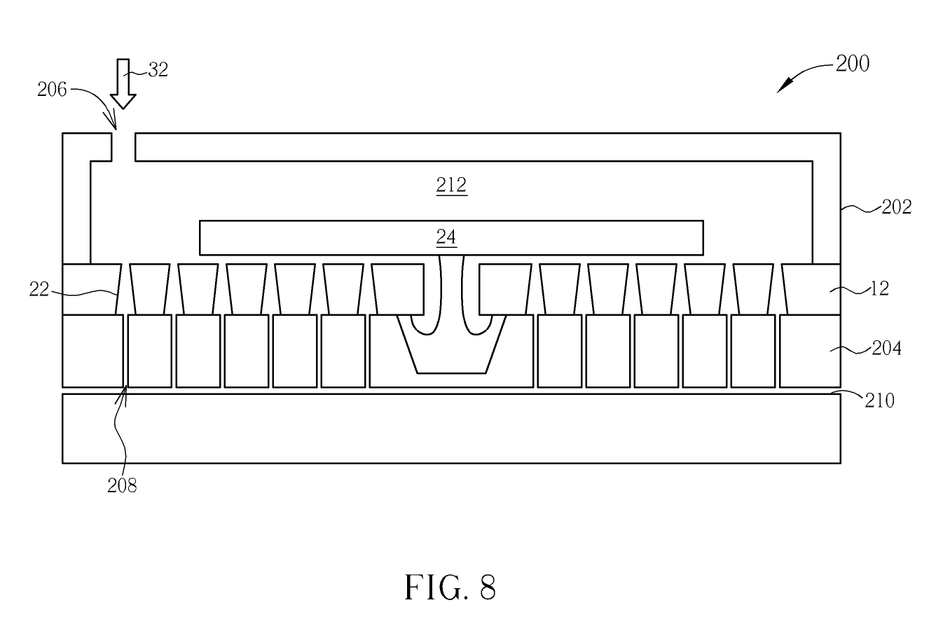

FIG. 7 depicts a variant of mold locks according to the second embodiment of the present invention. The elements with the same function are designated with the same numeral references in FIG. 6. Although each of the mold bump 133 is spherical shaped in FIG. 6, as shown in FIG. 7, each of the mold bump 133 can also be cubic shaped. Alternatively, other shapes such as a spheroid or hexagonal solid can be utilized as the shape of the mold bump 133 according to the present invention.

FIG. 8 depicts a mold for fabricating the mold body and the mold locks in FIG. 2. The same elements with the same function will be designated with the same numeral references in FIG. 2.

As shown in FIG. 8, a mold 200 includes an upper mold 202 and a lower mold 204. The upper mold 202 has an inlet 206 disposed on the upper mold 202. The lower mold 204 has a plurality of first vents 208, and each of the first vents 208 is disposed corresponding to a through hole 22 of the base 12. The lower mold 204 further includes a second vent 210 which connects to each of the first vents 208. During a press-molding process, the upper mold 202 and the lower mold 204 are pressed to each other together, the base 12 and the die 24 are sandwiched between the upper mold 202 and the lower mold 204, and a chamber 212 is created between the upper mold 202 and the package 10.

After that, the molding material 32 is injected into the chamber 212. When the molding material 32 flows into the through holes 22, the air inside the through holes 22 is pressed out through the first vents 208 and the second vent 210 by the molding material 32. Therefore, the molding material 32 can completely fills up the through holes 22 without air trapped inside of the molding material 32. Finally, after the molding material 32 fills up the chamber 212, the molding material 32 is cured and the desired mold body 36 and mold locks 34 in FIG. 2 is thus formed.

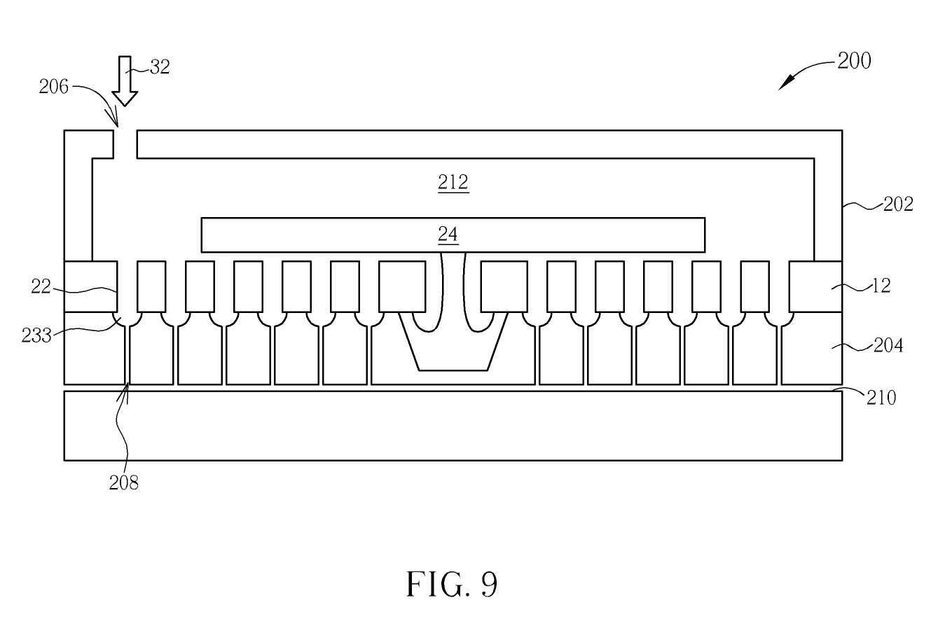

FIG. 9 depicts a mold for fabricating the mold body and the mold locks in FIG. 6. The same elements with the same function will be designated with the same numeral references in FIG. 6 and FIG. 8.

The primary difference between the mold in FIG. 8 and FIG. 9 is that the lower mold 204 in FIG. 9 has mold bump cavities for the formation of the mold bumps in FIG. 6.

Please refer to FIG. 9, a mold 200 includes an upper mold 202 and a lower mold 204. The upper mold 202 has an inlet 206 disposed on the upper mold 202. The lower mold 204 has a plurality of mold bump cavities 233 disposed corresponding to each of the through hole 22 for forming the mold bumps 133. Each of the mold bump cavities 233 communicates with one end of a first vent 208. The other end of each of the first vent 208 is connected to a second vent 210.

During a press-molding process, a chamber 212 is formed between the upper mold 202 and the base 12, and the upper mold 202 the die 24. After that, the molding material 32 is injected into the chamber 212. The molding material is pressed into the through holes 22 first, and then flows into the mold bump cavities 233. The air inside the through holes 22 and the mold bump cavities 233 is pressed out through the first vents 208 and the second vent 210 by the molding material 32. Finally, after the molding material 32 fills up the chamber 212, the molding material 32 is cured. A semiconductor chip package with mold locks is formed.

Although only spherical shaped mold bump cavities 233 is shown in FIG. 9, other shapes of the mold bump cavities 233 such as cubic shaped can be applied.

Since the mold locks and the mold body are formed by the molding material, and cured simultaneously, the mold locks and the mold body is an integral and monolithic structure. Therefore, the mold locks can provide adequate strength to affix the mold body to the base. Furthermore, to form the mold locks, only some vent holes are need to be formed on the mold. The fabricating steps for forming the chip package having mold locks are compatible with the conventional packaging and molding process.

Those skilled in the art will readily observe that numerous modifications and alterations of the device and method may be made while retaining the teachings of the invention.

What is claimed is:

1. A semiconductor chip package comprising:
a base comprising a top surface and a bottom surface, the top surface comprising a die attach region and a through-hole forming region surrounding the die attach region;
a die attached on the die attach region;
a molding material encapsulating the die; and
a plurality of through holes formed in the through-hole forming region and filled with the molding material.

2. The semiconductor chip package of claim 1, wherein each of the plurality of through holes has a tapered profile.

3. The semiconductor chip package of claim 2, wherein the tapered profile is in a bottle-like shape.

4. The semiconductor chip package of claim 2, wherein the tapered profile is in a form of a frustum cone.

5. The semiconductor chip package of claim 1, wherein each of the through holes is in a form of a cylinder.

6. The semiconductor chip package of claim 5 further comprising a plurality of mold bumps protruding from the bottom surface of the base and each of the plurality of mold bumps integrates with the molding material in each of the plurality of through holes.

7. The semiconductor chip package of claim 6, wherein each of the plurality of mold bumps is spherical shaped.

8. The semiconductor chip package of claim 6, wherein each of the plurality of mold bumps is cubic shaped.

9. The semiconductor chip package of claim 1, wherein the plurality of through holes are arranged in a staggered manner on the base.

10. The semiconductor chip package of claim 1, wherein the plurality of through holes are aligned with each other along each side edge of the base.

11. The semiconductor chip package of claim 1 further comprising a plurality of die conducting pads disposed on the die.

12. The semiconductor chip package of claim 11 further comprising a plurality of base conducting pads disposed on the top surface between the die attach region and the through-hole forming region.

13. A mold lock for a semiconductor chip package, comprising:
a molding material with a tapered profile inlaid into an outer edge of a base.

14. The mold lock for a semiconductor chip package of claim 13, wherein the base comprising a top surface.

15. The mold lock for a semiconductor chip package of claim 14, wherein a die is mounted on the top surface.

16. The mold lock for a semiconductor chip package of claim 15, wherein the tapered profile broadening from the top surface.

17. A mold lock for a semiconductor chip package, comprising:
a molding material inlaid into an outer edge of a base, wherein the molding material has a mold bump protruding from a bottom surface of the base.
